(19) United States
(12) Patent Application Publication
(10) Pub. No.: US 2018/0211930 A1
(43) Pub. Date: Jul. 26, 2018

(54) SEMICONDUCTOR DEVICE AND METHOD FOR MANUFACTURING THE SAME

(71) Applicant: TOYOTA JIDOSHA KABUSHIKI KAISHA, Toyota-shi (JP)

(72) Inventor: Naoya TAKE, Toyota-shi (JP)

(73) Assignee: TOYOTA JIDOSHA KABUSHIKI KAISHA, Toyota-shi (JP)

(21) Appl. No.: 15/846,903

(22) Filed: Dec. 19, 2017

(30) Foreign Application Priority Data
Jan. 24, 2017 (JP) 2017-010629

(51) Int. Cl. H01L 23/00

(52) U.S. Cl. CPC H01L 24/48; H01L 2224/05557; H01L 24/45; H01L 24/05; H01L 2224/04042; H01L 2224/45147; H01L 2224/05573; H01L 2224/48453; H01L 2224/05551; H01L 2224/05073; H01L 2224/05124; H01L 2924/0483; H01L 2224/05655; H01L 2224/48855; H01L 2224/85801; H01L 2224/85236; H01L 24/85

(57) ABSTRACT

A method of manufacturing a semiconductor device including: bonding a wire constituted of copper on an electrode pad provided on a surface of a semiconductor substrate, wherein the electrode pad includes a hard metal layer harder than the wire as a surface layer of the electrode pad, a recess is provided in a surface of the hard metal layer, the wire before the bonding includes a linear portion and a ball portion provided at a distal end of the linear portion and having a diameter larger than a diameter of the linear portion, and the ball portion is bonded in the recess in the bonding.

### TECHNICAL FIELD

The technique disclosed herein relates to a semiconductor device and a method of manufacturing the same.

### BACKGROUND

Japanese Patent Application Publication No. 2013-004781 describes a technique that bonds a wire constituted of copper (hereinbelow referred to as a copper wire) to an electrode pad provided on a surface of a semiconductor substrate. Since the copper wire is hard as compared to an aluminum wire and a gold wire, there may be a case where the semiconductor substrate underneath the electrode pad may be damaged upon bonding the copper wire. With respect to this, the technique in Japanese Patent Application Publication No. 2013-004781 suppresses such damage to the semiconductor substrate by providing a hard metal layer on a surface layer of the electrode pad.

### SUMMARY

When a copper wire is to be bonded, a ball portion is formed at a distal end of the copper wire, and this ball portion is pressed onto an electrode pad. Due to this, an connection is made to the electrode pad while the ball portion is squashed. If a hard metal layer that is harder than the copper wire is provided on a surface layer of the electrode pad as in Japanese Patent Application Publication No. 2013-004781, the ball portion is more easily squashed upon the bonding. As a result, a diameter of a distal end portion of the copper wire after the bonding (a diameter of the squashed ball portion) becomes larger. If a size of the distal end portion of the copper wire after the bonding is large, a size of the electrode pad needs to be made large correspondingly. Due to this, it becomes difficult to reduce a semiconductor device size. Thus, in the disclosure herein, a technique that suppresses damage to a semiconductor substrate and suppresses a size of a distal end portion of a copper wire after bonding from becoming large is provided.

A method of manufacturing a semiconductor device disclosed herein may comprise: bonding a wire constituted of copper on an electrode pad provided on a surface of a semiconductor substrate. The electrode pad may comprise a hard metal layer harder than the wire as a surface layer of the electrode pad. A recess may be provided in a surface of the hard metal layer. The wire before the bonding may comprise a linear portion and a ball portion provided at a distal end of the linear portion and having a diameter larger than a diameter of the linear portion. The ball portion may be bonded in the recess in the bonding.

In the disclosure herein, the hardness refers to Vickers hardness.

In this manufacturing method, the copper wire is bonded to the hard metal layer. Thus, damage to the semiconductor substrate underneath the hard metal layer is suppressed. Further, in this manufacturing method, the recess is provided in the surface of the hard metal layer, and the ball portion of the copper wire is bonded in the recess. Due to this, the ball portion is squashed within the recess. Accordingly, the squashed ball portion is suppressed from flowing out of the recess to its periphery, and a size of the squashed ball portion is suppressed from enlarging. Thus, according to this manufacturing method, the size of the distal end portion of the copper wire after the bonding can be made smaller than in the conventional methods.

### BRIEF DESCRIPTION OF DRAWINGS

FIG. 1 shows a plan view of a semiconductor substrate 12.

FIG. 2 shows a cross sectional view along a line II-II in FIG. 1.

FIG. 3 is an explanatory diagram of bonding.

FIG. 4 is an explanatory diagram of the bonding.

FIG. 5 is an explanatory diagram of bonding of a semiconductor device of a variant.

FIG. 6 is a cross sectional view of the semiconductor device of the variant corresponding to FIG. 2.

FIG. 7 is an explanatory diagram of bonding of a semiconductor device of another variant.

FIG. 8 is a cross sectional view of the semiconductor device of the other variant corresponding to FIG. 2.

### DETAILED DESCRIPTION

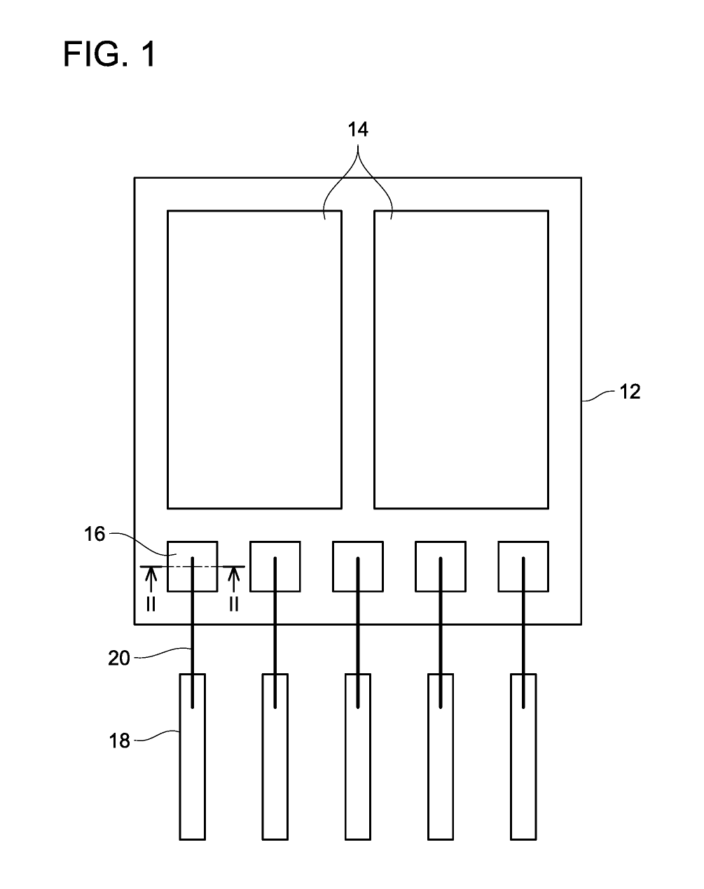

FIG. 1 shows an upper surface of a semiconductor device. The semiconductor device includes a semiconductor substrate 12. The semiconductor substrate 12 is constituted of a semiconductor of which primary component is Si (silicon). The semiconductor substrate 12 may be constituted of a wide bandgap semiconductor of which primary component is SiC (silicon carbide), GaN (gallium nitride), or the like. Main electrodes 14 and signal electrode pads 16 are provided on an upper surface of the semiconductor substrate 12. A size of each signal electrode pad 16 is smaller than a size of each main electrode 14. The main electrodes 14 are connected to a wiring member, which is not shown, by solder. A plurality of lead wires 18 is arranged adjacent to one side of the semiconductor substrate 12. The respective signal electrode pads 16 are connected to their corresponding lead wires 18 by copper wires 20. Further, although not shown, a lower electrode is provided on a lower surface of the semiconductor substrate 12. The lower electrode is connected to a wiring member, which is not shown, by solder.

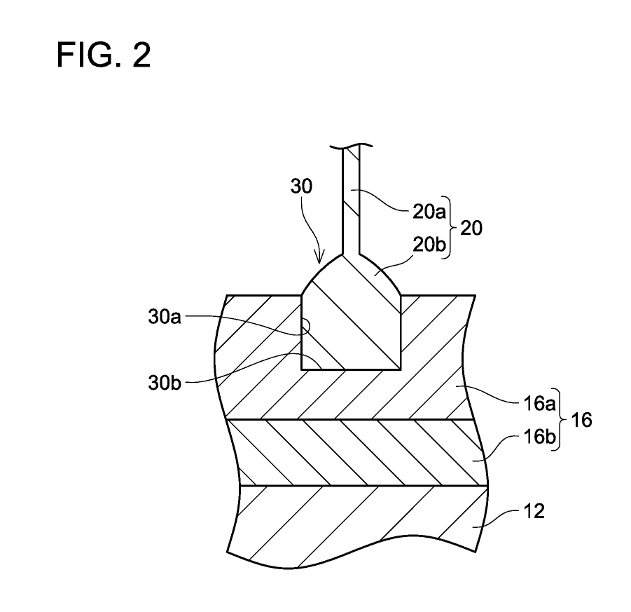

FIG. 2 shows a cross section of one of the signal electrode pads 16 along a line II-II in FIG. 1. As shown in FIG. 2, the signal electrode pad 16 includes a hard metal layer 16a and a soft metal layer 16b.

The soft metal layer 16b is arranged on the semiconductor substrate 12. The soft metal layer 16b is constituted of Al (aluminum) or AlSi (aluminum-silicon alloy). The soft metal layer 16b has a Vickers hardness that is lower than that of the copper wire 20. The soft metal layer 16b is in contact with the upper surface of the semiconductor substrate 12. It should be noted that, with a signal electrode pad 16 of another embodiment, an insulating film may be arranged between the soft metal layer 16b and the semiconductor substrate 12, and the soft metal layer 16b may be insulated from the semiconductor substrate 12. Further, another metal layer may be arranged between the soft metal layer 16b and the semiconductor substrate 12.

The hard metal layer 16a is arranged on the soft metal layer 16b. The hard metal layer 16a is constituted of Ni (nickel). The hard metal layer 16a has a Vickers hardness that is higher than that of the copper wire 20. The hard metal layer 16a is in contact with an upper surface of the soft metal layer 16b. It should be noted that, with a signal electrode pad 16 of another embodiment, another metal layer may be arranged between the hard metal layer 16a and the soft metal layer 16b. A recess 30 is provided in a surface of the hard metal layer 16a. The recess 30 has a columnar shape in which its center axis extends vertical to the surface of the hard metal layer 16a. The recess 30 includes a lateral surface 30a and a bottom surface 30b. Entireties of the lateral surface 30a and the bottom surface 30b are constituted of the hard metal layer 16a.

The copper wire 20 includes a linear portion 20a with a small diameter and a distal end 26 portion 20b with a large diameter. The distal end portion 20b is bonded inside the recess 30. The distal end portion 20b fills the inside of the recess 30 with no gap therebetween. Thus, the distal end portion 20b is in contact with the entire lateral surface 30a and the entire bottom surface 30b of the recess 30. The linear portion 20a extends upward from the distal end portion 20b. The other end of the linear portion 20a is connected to the lead wire 18.

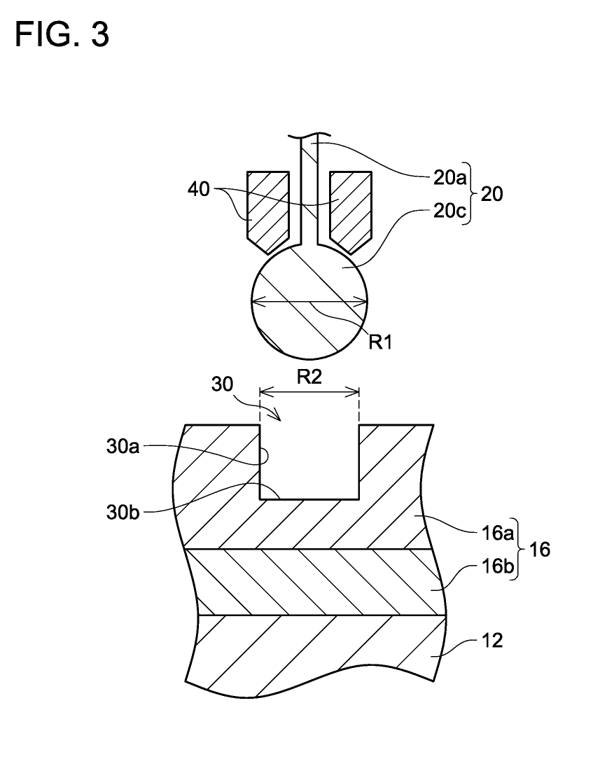

In a manufacturing process of the semiconductor device shown in FIGS. 1 and 2, wire bonding that bonds the copper wires 20 to the signal electrode pads 16 is performed. A wire bonding device used in the wire bonding includes a capillary 40 shown in FIG. 3. The copper wire 20 is inserted through a center hole of the capillary 40, and a distal end of the copper wire 20 protrudes downward from a distal end of the capillary 40. In the wire bonding, a ball portion 20c shown in FIG. 3 is formed by melting the distal end of the copper wire 20 once by electric discharge. The ball portion 20c has a substantially ball shape. A diameter R1 of the ball portion 20c is larger than the diameter of the linear portion 20a. Further, the diameter R1 of the ball portion 20c is larger than a width R2 of the recess 30 (diameter of the columnar shape). An inner volume of the recess 30 is larger than a half of a volume of the ball portion 20c, but smaller than the volume of the ball portion 20c. Further, the signal electrode pad 16 is heated by the wire bonding device during the wire bonding.

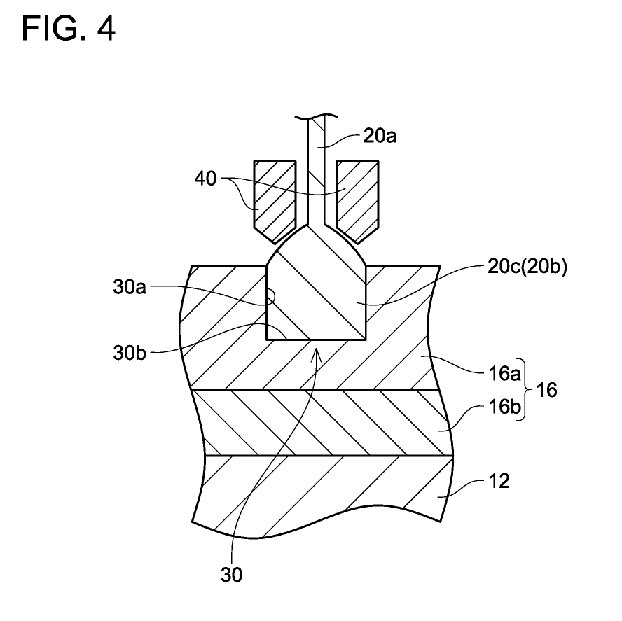

Next, as shown in FIG. 4, the capillary 40 is moved toward the recess 30 to insert the ball portion 20c into the recess 30. By so doing, the ball portion 20c is pressed against the recess 30. Further, concurrently as pressing the ball portion 20c to the recess 30, ultrasound waves are applied to the ball portion 20c by the capillary 40. Due to this, the ball portion 20c is connected to the hard metal layer 16a within the recess 30. After the ball portion 20c is connected to the hard metal layer 16a, the other end portion of the copper wire 20 is bonded to the lead wire 18.

As aforementioned, the diameter R1 of the ball portion 20c before the bonding is larger than the diameter R2 of the recess 30. Due to this, the ball portion 20c deforms when the ball portion 20c is inserted into the recess 30. That is, the ball portion 20c is press-fitted into the recess 30. As such, the ball portion 20c is pressed not only against the bottom surface 30b of the recess 30, but also against the lateral surface 30a of the recess 30 under a large load. As a result, the deformed ball portion 20c becomes the distal end portion 20b contacting the lateral surface 30a and the bottom surface 30b, as shown in FIG. 4. Generally, when a ball portion is bonded to a flat electrode pad, the ball portion is squashed in a vertical direction (thickness direction of the electrode pad), and also spreads along a lateral direction (direction parallel to an upper surface of the electrode pad). Due to this, a distal end portion of a copper wire comes to have a shape in which its diameter has enlarged in the lateral direction compared to the ball portion before the bonding. Contrary to this, when the ball portion 20c is bonded inside the recess 30 as in FIG. 4, the ball portion 20c is suppressed from spreading in the lateral direction due to the lateral surface 30a of the recess 30. Especially in the present embodiment, the volume of the ball portion 20c, the inner volume of the recess 30, and the load applied to the ball portion 20c by the capillary 40 are adjusted so that the squashed ball portion 20c does not flow out from the recess 30 to a periphery thereof. Thus, a diameter of the distal end portion 20b in the lateral direction becomes smaller than the diameter R1 of the ball portion 20c before the bonding. In this embodiment, the diameter of the distal end portion 20b in the lateral direction becomes substantially equal to the diameter R2 of the recess 30. According to this wire bonding, a size (lateral size) of the distal end portion 20b of the copper wire 20 after the bonding can be made smaller than in conventional configurations. Due to this, a size of the signal electrode pads 16 can be made smaller than in conventional configurations. As a result, the semiconductor substrate 12 can be made smaller than in conventional configurations.

Further, according to this wire bonding, the distal end portion 20b of the copper wire 20 can be brought into contact with not only the bottom surface 30b but also the lateral surface 30a of the recess 30. Due to this, a wide bonding surface between the copper wire 20 and the hard metal layer 16a can be achieved, and strength of the bonding surface can be improved. Further, since an area of the bonding surface becomes broader, a current density in the bonding surface can be reduced. Thus, when overcurrent flows in the copper wires 20, heat generation at the bonding surfaces can be suppressed.

Further, since the hard metal layer 16a is hard, the hard metal layer 16a underneath the ball portion 20c is less likely to deform toward the semiconductor substrate 12 when the ball portion 20c is pressed against the hard metal layer 16a. Further, since the soft metal layer 16b is arranged underneath the hard metal layer 16a, the load applied to the hard metal layer 16a is less likely to be transmitted to the semiconductor substrate 12. Thus, in the wire bonding the load applied to the semiconductor substrate 12 underneath the signal electrode pads 16 can be suppressed. According to this method, damage to the semiconductor substrate 12 underneath the signal electrode pads 16 can be suppressed.

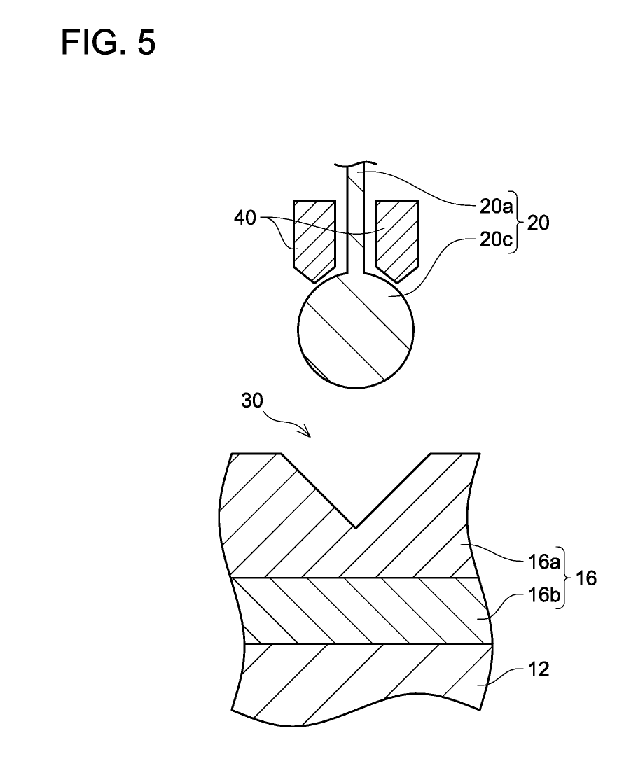

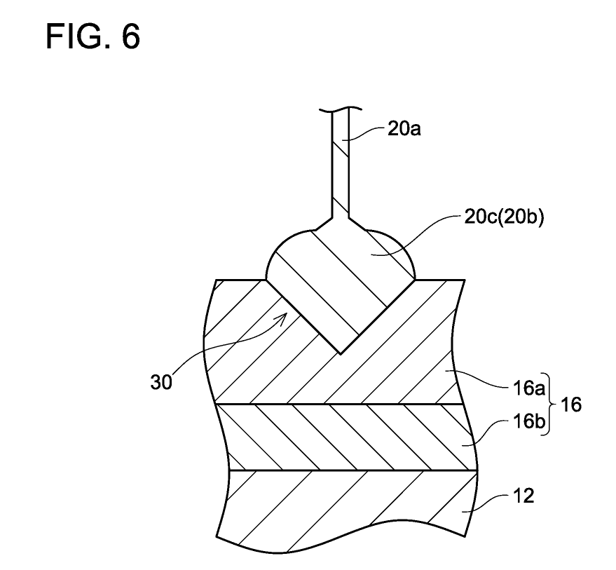

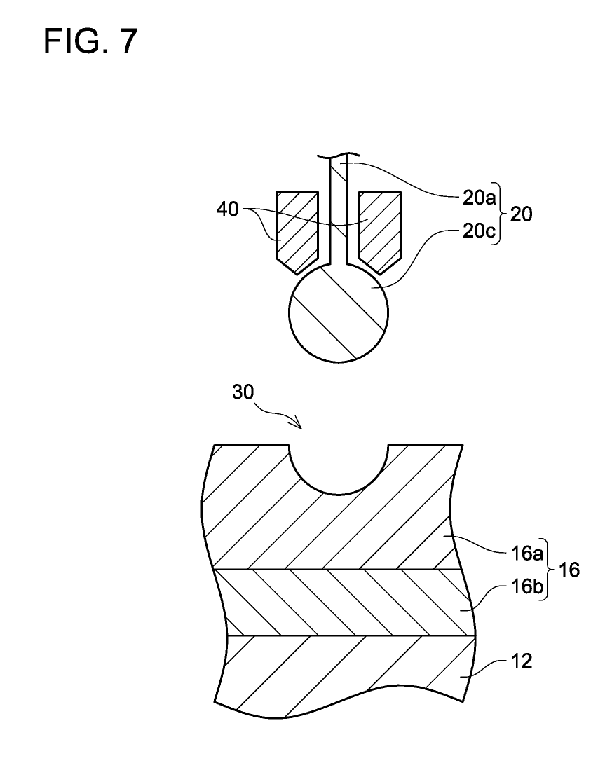

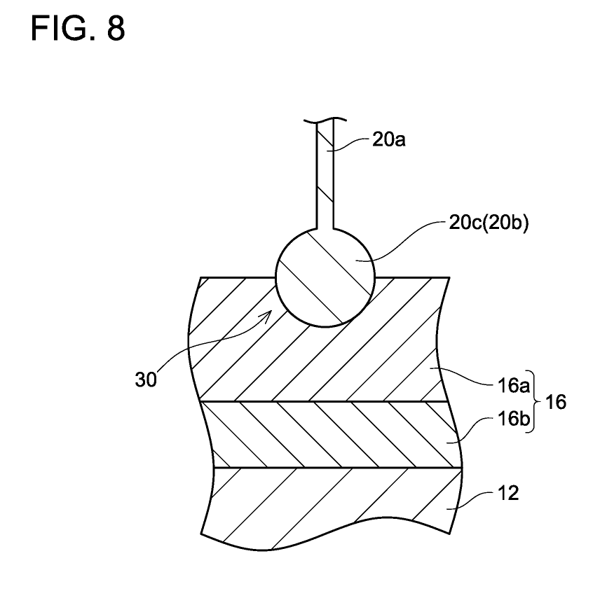

In the aforementioned embodiment, the recess 30 had the columnar shape. However, the shape of the recess 30 can suitably be modified. For example, the recess 30 may have a shape of a square block, a rectangular parallelepiped, or a slit. In any of these cases, the distal end portion 20b of the copper wire 20 can be brought into contact with the lateral surface of the recess 30 by making the width of the recess 30 narrower than the diameter of the ball portion. Further, for example, as shown in FIGS. 5 and 6, the recess 30 may be given a cone shape (shape in which its diameter becomes smaller at deeper positions). Further, as shown in FIGS. 7 and 8, the recess 30 may be given a semispherical shape. In any of the configurations of FIGS. 5 to 8, when the ball portion 20c of the copper wire 20 is pressed against the hard metal layer 16a, the squashed ball portion 20c can be suppressed from spreading from the recess 30 to the periphery thereof. Thus, the size of the distal end portion 20b of the copper wire 20 after the bonding can be made smaller than in conventional configurations.

In the aforementioned embodiment, the distal end portion 20b of the copper wire 20 did not overflow from the recess 30 to the periphery thereof. However, in another embodiment, a distal end portion of a copper wire may overflow from a recess to a periphery thereof. According to such a configuration as well, the recess allows to suppress a squashed ball portion from spreading in the lateral direction as compared to a case where the recess is not provided.

Some of the features characteristic to the disclosure herein will be listed. It should be noted that the respective technical elements are independent of one another, and are useful solely or in combinations.

In a configuration example disclosed herein, the recess may comprise a bottom surface and a lateral surface. Further, the ball portion may be brought into contact with the bottom surface and the lateral surface in the bonding.

According to this configuration, a bonding surface of the copper wire and the hard metal layer can be made broad. Thus, strength of the bonding surface can be improved, and a current density in the bonding surface can be reduced.

In a configuration example disclosed herein, a width of the recess may be narrower than the diameter of the ball portion before the bonding.

According to this configuration, the ball portion of the copper wire can be brought into contact with a wide range of an inner surface of the recess upon bonding.

In a configuration example disclosed herein, an inner volume of the recess may be larger than a half of a volume of the ball portion before the bonding.

According to this configuration, a distal end portion of the copper wire can be suppressed from overflowing from the recess to a periphery thereof.

In a configuration example disclosed herein, the electrode pad may comprise a soft metal layer interposed between the hard metal layer and the semiconductor substrate, and being softer than the wire.

According to this configuration, damage to the semiconductor substrate can more suitably be suppressed.

Specific examples of the present disclosure have been described in detail, however, these are mere exemplary indications and thus do not limit the scope of the claims. The art described in the claims include modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

What is claimed is:

1. A method of manufacturing a semiconductor device, the method comprising:
bonding a wire constituted of copper on an electrode pad provided on a surface of a semiconductor substrate,
wherein
the electrode pad comprises a hard metal layer harder than the wire as a surface layer of the electrode pad,
a recess is provided in a surface of the hard metal layer,
the wire before the bonding comprises a linear portion and a ball portion provided at a distal end of the linear portion and having a diameter larger than a diameter of the linear portion, and
the ball portion is bonded in the recess in the bonding.

2. The method of claim 1, wherein
the recess comprises a bottom surface and a lateral surface, and
the ball portion is brought into contact with the bottom surface and the lateral surface in the bonding.

3. The method of claim 1, wherein a width of the recess is narrower than the diameter of the ball portion before the bonding.

4. The method of claim 1, wherein an inner volume of the recess is larger than a half of a volume of the ball portion before the bonding.

5. The method of claim 1, wherein
the electrode pad comprises a soft metal layer interposed between the hard metal layer and the semiconductor substrate, and
the soft metal layer is softer than the wire.

6. A semiconductor device, comprising:
a semiconductor substrate;
an electrode pad provided on a surface of the semiconductor substrate; and
a wire connected to the electrode pad and constituted of copper,
wherein
the electrode pad comprises a hard metal layer harder than the wire as a surface layer of the electrode pad,
a recess is provided in a surface of the hard metal layer, and
the wire is connected to an inside of the recess.

7. The semiconductor device of claim 6, wherein
the recess comprises a bottom surface and a lateral surface, and
the wire is in contact with the bottom surface and the lateral surface.

8. The semiconductor device of claim 6, wherein
the electrode pad comprises a soft metal layer interposed between the hard metal layer and the semiconductor substrate, and
the soft metal layer is softer than the wire.
